(19) United States
(12) Patent Application Publication
(10) Pub. No.: US 2007/0057666 A1
(43) Pub. Date: Mar. 15, 2007

(54) Defect inspection system and method for recording media

(76) Inventors: Tomokazu Shimakura, Kokubunji (JP); Teruo Kohashi, Hachioji (JP); Yoshio Takahashi, Koganei (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/492,964

(22) Filed: Jul. 26, 2006

(30) Foreign Application Priority Data
Sep. 13, 2005 (JP) 2005-264700

(51) Int. Cl. G01R 33/12

(52) U.S. Cl. 324/212

(57) ABSTRACT

This invention provides a recording media defect inspection technique that makes possible high-speed and high-resolution defect inspection using an electron beam. A spindle motor rotates a recording media while an electron beam is being irradiated on a surface of a recording media, and detectors detect secondary electrons produced from the recording media, whereby unevenness information of the recording media surface is obtained. The obtained unevenness information on the recording media surface is Fourier transformed and a defect is detected. Further, by introducing deposition gas onto the recording media surface by gas introduction means while irradiating the electron beam on the recording media, a component of the deposition gas is deposited in a detected defect position on the recording media surface to form a mark.

### CLAIM OF PRIORITY

The present invention claims priority from Japanese application JP 2005-264700 filed on Sep. 13, 2005, the content of which is hereby incorporated by reference on to this application.

### BACKGROUND OF THE INVENTION

This invention relates to a defect inspection technique, and especially to a recording media inspection technique of inspecting the existence of a defect and its kind including unevenness of a surface or a foreign material adhered thereon of a magnetic recording media used for a magnetic disk drive, an optical recording media used for an optical disk drive, etc.

The magnetic disk drive, comprising a magnetic head and a magnetic recording media, performs recording data on the magnetic recording media and reading data from the magnetic recording media with the magnetic head by flying the magnetic head off the disk by rotating the magnetic recording media. As the capacity of the magnetic disk grows larger, a stronger writing magnetic field becomes necessary, and a flying height between the magnetic head and the magnetic recording media is required to be smaller. The methods for reducing a distance between the magnetic head and the magnetic recording media include a method for lowering the flying height of the magnetic head and a method for thinning an overcoat formed on the magnetic recording media. If the flying height of the magnetic head is made too small, the magnetic head may collide even with a slight projection on the magnetic recording media, which will destroy the magnetic head or the magnetic recording media. If the overcoat is made too thin, it may cause degradation in collision resistance of the magnetic recording media, which will lead to degradation in reliability of the magnetic disk drive. Therefore, in case where a defect occurs on the magnetic recording media, it is required to identify a defect position, analyze a defect cause, and take prompt measures against it.

The following techniques are known as conventional defect inspection systems of a magnetic recording media. For example, Japanese Patent Application Laid-Open No. 2002-365232 proposes an optical defect inspection system. This system irradiates laser light on a surface of the magnetic recording media and inspects the existence of a defect by means of deflection of its reflected light. Moreover, an optical inspection system that has a stage translation mechanism and a mechanism for making a scratch on a surface of the magnetic recording media in order to form a mark in the vicinity of the detected defect is also known. This system translates a specimen after a laser detected a defect and scratches the specimen surface mechanically using a diamond tool or the like.

Moreover, Japanese Patent Application Laid-Open No. 2004-349515 proposes a defect inspection system mainly of semiconductor wafers using an electron beam. This defect inspection system using an electron beam detects secondary electrons produced by the surface with a scanning electron microscope, finds the existence or absence of a defect, and classifies the kind of the foreign matter from its shape.

### SUMMARY OF THE INVENTION

In order to further improve recording density, the flying height of the magnetic head shows a tendency to become smaller. If the flying height goes down to 10 nm or less, even a defect of a protrusion of a height of a few nanometers on the magnetic recording media will become a problem. However, resolution of the above-mentioned optical defect inspection system is only about 100 nm, and minute defects not detectable by the optical defect inspection systems have become a problem. Moreover, since even if a defect is detected and a mark is put in the vicinity of the defect, it is difficult for other analyzing system to identify a position of a defect, the size of which is a few tens of nanometers, from the mark and analyze the defect because positional accuracy of the mark is of the order of a few tens of micrometers.

On the other hand, in the case where the magnetic recording media surface is inspected with an electron beam, a maximum resolution is 1 nm or less, and accordingly the resolution satisfies the requirement. However, unlike single crystal materials, such as a semiconductor wafer, a magnetic layer of the magnetic recording media is composed of grain with a diameter of 20 nm or less. Therefore, there exists unevenness of mean surface roughness of about 1 nm resulting from the grain. Since the electron beam method has high resolution, the unevenness by the grain introduces noise; therefore, it has posed a problem that the unevenness by a defect is difficult to detect.

In view of this, the object of this invention is to provide a defect inspection technique for a recording media that solves the above-mentioned problems and makes possible high-speed and high-resolution defect inspection using an electron beam.

In order to attain the object, the defect detection system according to this invention is configured to irradiate an electron beam on a surf ace of a specimen (for example, recording media), detect electrons produced secondarily from the surface, acquire unevenness information of the specimen surf ace, process the unevenness information of the specimen surface or differentiation values of the unevenness by Fourier transform, and detect the defect. Arithmetic processing of acquisition of the unevenness information, differentiation, Fourier transform, or the like is processed by arithmetic means installed in the system or appropriate arithmetic means connected to the system through a network line. Furthermore, deposition gas is introduced to the vicinity of the defect position, and a mark is formed by an electron beam.

Hereafter, typical configuration examples according to this invention will be enumerated.

(1) A defect inspection system for a recording media of this invention, is characterized by having: an electron optics system for irradiating and scanning a recording media surface with an electron beam emitted from an electron source through a deflection electrode and a focusing lens; position control means for rotating and translating the recording media; detection means for detecting electrons produced secondarily from the recording media surface; means for calculating unevenness information of the recording media or unevenness differentiation values from a signal of the detection means; means for detecting a defect of the recording media surface by Fourier transforming the unevenness information or differentiation values of the unevenness; and gas introduction means for introducing deposition gas onto the recording media surface.

(2) The above-mentioned defect inspection system for a recording media, is characterized by that the focusing lens can vary a spot size of the electron beam being irradiated on the recording media.

(3) The above-mentioned defect inspection system for a recording media, is characterized by that, in the case where the recording media is a magnetic recording media, the electron beam spot size is not less than the gain size and not more than the defect size being intended to be detected.

(4) The above-mentioned defect inspection system for a recording media, is characterized by that the position control means has a spindle motor for rotating the recording media and a feed stage for translating the recording media in X-Y directions in the recording media plane, and by being configured so as to rotate the recording media while irradiating an electron beam on the recording media, and detect electrons produced secondarily from the recording media surface.

(5) The above-mentioned defect inspection system for a recording media, is characterized by that the detection means has two or more secondary electron detectors and calculates unevenness information or unevenness differentiation values of the recording media surface from differences between signal quantities of the opposing secondary electron detectors.

(6) The above-mentioned defect inspection system for a recording media, is characterized by depositing a component of the deposition gas in an electron beam irradiation area on the recording media surface to form a mark by introducing the deposition gas while irradiating the electron beam on the recording media.

(7) The above-mentioned defect inspection system for a recording media, is characterized by that the electron beam spot size on the recording media surface at the time of introducing the deposition gas is a spot size of the electron beam that is made narrowest by a capability of the focusing lens.

(8) A defect inspection method for a recording media of this invention, is characterized by comprising the steps of: detecting electrons produced secondarily from the recording media by rotating the recording media while irradiating an electron beam on a surface of the recording media; calculating unevenness information of the recording media surface or unevenness differentiation values from a detected signal; detecting a defect on the recording media surface by Fourier transforming the unevenness information or unevenness differentiation values; and depositing a component of deposition gas in a detected defect position on the recording media surface to form a mark by introducing the deposition gas onto the recording media while irradiating the electron beam on the recording media.

(9) The above-mentioned defect inspection method for a recording media, is characterized in that the unevenness of the recording media surface or a group of the differentiation values is one- or two-dimensional information.

(10) The above-mentioned defect inspection method for a recording media, is characterized in that in the case where the recording media is a magnetic recording media, wavelength components corresponding to not more than a desired value that exists between the grain size of the magnetic recording media and a defect size being intended to be detected is removed from information obtained by Fourier transforming the unevenness information of the recording media surface or differentiation values.

(11) The above-mentioned defect inspection method, is characterized in that a wavelength component of a continuous structure that is artificially made on the recording media surface is removed from the Fourier transformed information from which wavelength components corresponding to not more than the desired value are removed.

(12) The above-mentioned defect inspection method, is characterized in that the Fourier transformed information is performed further inverse Fourier transformation and the obtained information is used to detect a defect on the recording media surface.

(13) A defect inspection system for a recording media of this invention, is characterized by having: an electron optics system for irradiating and scanning a magnetic recording media with an electron beam emitted from an electron source through a deflection electrode and a focusing lens; position control means for rotating and translating the magnetic recording media; detection means equipped with two or more detectors for detecting secondary electrons from the magnetic recording media surface; means for calculating unevenness information of the magnetic recording media surface or unevenness differentiation values from differences between signal quantities of the opposing detectors, means for detecting a defect on the magnetic recording media surface by Fourier transforming the unevenness information or unevenness differentiation values; gas introduction means for introducing deposition gas onto the magnetic recording media surface; and means for depositing a component of the deposition gas in the electron beam irradiation area on the magnetic recording media surface to form a mark by introducing the deposition gas onto the magnetic recording media while irradiating the electron beam thereon.

According to this invention, there can be provided a recording media defect inspection technique that makes possible high-speed and high-resolution defect inspection using an electron beam. In addition, there can be provided a recording media defect inspection technique that can form a mark in the vicinity of a defect.

### BRIEF DESCRIPTION OF THE DRAWINGS

FIG. 1 is a diagram explaining a configuration of a defect inspection system that is one embodiment of this invention;

FIGS. 2A, 2B, and 2C are diagrams schematically showing trajectories of an electron beam according to this invention;

FIG. 3 is a signal waveform diagram showing one example of a defect;

FIG. 4 is a signal waveform diagram processed by a defect detection method according to this invention;

FIGS. 5A, 5B are diagrams showing the cases where the recording media is a discrete track media, respectively; and

FIGS. 6A, 6B are diagrams showing the cases where the recording media is a patterned media, respectively.

### DETAILED DESCRIPTION OF THE PREFERRED EMBODIMENTS

Hereafter, an embodiment of this invention will be described in detail with reference to the drawings.

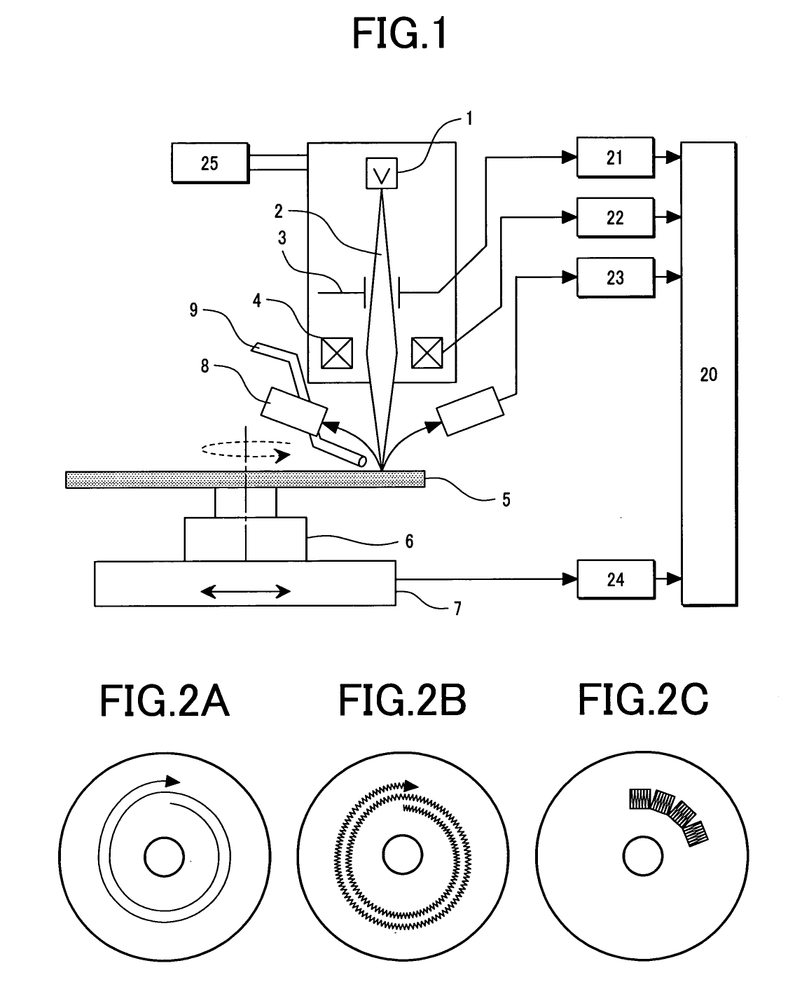

FIG. 1 shows a configuration example of a defect inspection system that is one embodiment of this invention. The one embodiment of this invention is constructed with an electron optics system, a stage mechanism system, a control system, and a vacuum pumping system 25. The electron optics system comprises an electron source 1, deflection electrodes 3, focusing lenses 4, and detectors 8. The stage mechanism system comprises a spindle motor 6 and a feed stage 7 that are position control means. The control system comprises an image processing operation control 20, a beam deflection control 21, an electron optics control 22, a signal detection control 23, and a stage control 24. Although not illustrated, the image processing operation control 20 has image input means, such as a mouse, a keyboard, or a button, and image display means for displaying an acquired image, by which the system user can enter information necessary for a control into the system.

First, an electron beam 2 emitted from the electron source 1 passes through the deflection electrode 3, is focused by the focusing lens 4, and irradiated on a specimen 5 that is a media under measurement. The focusing lens 4 is an electromagnetic-field lens, being capable of altering the spot size of the electron beam 2 being irradiated on the specimen 5 by adjusting the amount of a current flowing in a coil. The surface of the specimen 5 can be scanned with the electron beam 2 by applying a voltage to the deflection electrode 3.

The spindle motor 6 and the feed stage 7 that constitute the position control means enable the specimen 5 to be rotated in a specimen plane and translated in the X-Y directions in the X-Y plane and in a Z-direction. For this purpose, the feed stage 7 is provided with the translation mechanisms in the X-Y plane and in the Z-direction, and accordingly the specimen under inspection can be translated along with the rotating axis of the spindle motor. The stage control 24 conducts stage position control in the X-Y plane and in the Z-direction.

When the specimen 5 is, for example, a disk-shaped magnetic recording media, the disk is translated in a radial direction by the feed stage 7 while being rotated by the spindle motor 6. As a result, the trajectory of the electron on the specimen becomes spiral as shown in FIG. 2A. Alternatively, the specimen 5 may be scanned in its radial direction using the deflection electrode 3 while being rotated by the spindle motor 6 and at the same time being translated in a radial direction by the feed stage 7. In this case, as shown in FIG. 2B, a trajectory of the electron on the specimen becomes such that a trajectory of a beam scan having a constant deflection width moves in a spiral on the magnetic recording media surface. Alternatively, the magnetic media surface is divided into predetermined deflection areas and beam scanning is performed in each area sequentially. In this case, the following steps maybe adopted. After completion of electron beam scanning in a certain deflection area, the feed stage 7 and the spindle motor 6 are so driven that the next deflection area is moved to an irradiation position of the primary electron beam. Subsequently, a step of stopping the feed stage 7 and the spindle motor 6 and scanning the electron beam in the next deflection area is repeated. In this case, a trajectory of the electron on the specimen becomes like FIG. 2C. A rectangular area shown in FIG. 2C corresponds to a deflection area.

Regarding a difference in the effectiveness by the difference in a scan mode, in the case of FIGS. 2A and 2B, there is no dead time when no measurement is performed because the electron beam is always being scanned, and the measuring time can be shortened. On the other hand, in the case of FIG. 2C, a dead time occurs because no measurement is performed during when the feed stage 7 or the spindle motor 6 is being translated, and the measuring time tends to be longer. However, since the specimen is stationary during measurement, the specimen is hard to vibrate easily; therefore, high-resolution measurement is possible. For this reason, the user-friendliness of the system improves by displaying an input requirement in which the system user can select any scanning method considered suitable for a measurement purpose and allowing the user to specify the proper scanning method.

When the electron beam is irradiated on the specimen 5, a specimen surface emits secondary electrons that are produced secondarily therefrom as well as reflected electrons. Two or more secondary electron detectors or reflected electron detectors are provided as the detectors 8 for catching these electrons. Preferably, two or more secondary electron detectors are provided. If the two detectors 8 are provided, each detector is installed so as to be rotational symmetry to the other with respect to the primary electron beam incident on the specimen 5 or an optical axis of the primary electron beam. The largest number of secondary electrons is generated in the normal direction of the specimen.

If there is no defect in the irradiation area of the electron beam 2 on the specimen 5, the two detectors 8 detect the same quantity of secondary electrons. When the irradiation area of the specimen 5 being irradiated by the electron beam 2 has a defect and accordingly unevenness exists on the surface, the detected quantity of secondary electrons differs between the two detectors 8. When the difference in the quantity of secondary electrons between the two detectors 8 is displayed, it becomes possible to obtain an image corresponding to inclination of the surface shape, i.e., differentiation.

Grain with a diameter of 20 nm or less gathers with its crystal orientation being aligned to form the magnetic recording media or a magnetic layer contained in the magnetic recording media. Therefore, there is unevenness of mean surface roughness of about 1 nm resulting from this grain structure. In the case of the specimen 5 that is a magnetic recording media, when the electron beam 2 is converged thinly, resolution will become high but unevenness due to the grain will be also detected, which causes a signal from a defect to be buried by a signal from the unevenness due to the grain. Then, it is preferable to adjust the spot size of the electron beam 2 on the surface of the specimen 5 to be not less than the media grain size and not more than a defect size being intended to be detected by adjusting an exciting current of the focusing lens 4. Since the unevenness resulting from the grains of the media will be averaged, it will be buried in the background. As a result, it becomes easy to detect a defect from the acquired image.

In order to adjust the spot size of the electron beam easily, the image processing operation control 20 is provided with storage means for storing information of the spot size of the electron beam and information of control parameters, by which the beam spot size is rendered to a desired dimension, for example, a Z-axis direction position of the feed stage 7, a specimen thickness, an exciting current of the focusing lens 4, etc.

When the system user selects an appropriate spot size from a list of electron beam spot sizes displayed on a display screen, the image processing operation control 20 calls the control parameters based on the entered spot size and transfers them to the electron optics control 22. The electron optics control 22 adjusts the spot size of the electron beam based on the transferred information. In order to make the operation simpler, the system is configured to display the grain size, not the electron beam spot size, and allow the system user to enter information of desired resolution of defect inspection. The image processing operation control 20 selects an optimum spot size of the electron beam based on the entered size information of the magnetic grain, and calls the control parameters corresponding to the spot size. The called control parameters are transferred to the electron optics control 22, and used to adjust the electron optics system.

In order to determine whether a detected defect is a real defect or a feature erroneously detected, what is necessary is to reduce the spot size of the electron beam 2 as small as is used in a normal scanning electron microscope, scan again a location that is expected to have a defect, and determine a real defect from a higher resolution image. If the spot size of the electron beam is enlarged, the pitch by which the electron beam is scanned can be enlarged, being also effective in shortening a scan time.

Next, after the defect is detected, a mark is formed in the vicinity of a defect position using the electron beam. Specifically, gas introduction means 9 is brought close to the electron beam irradiation area on the specimen, and the specimen 5 is scanned by the electron beam 2 while introducing deposition gas, such as tungsten hexacarbonyl gas (WCO₆). By doing this, tungsten accumulates in the electron beam irradiation area. Since the electron beam is used, it is possible to form a mark in the extreme vicinity of a defect with accuracy of not more than 10 nm. Using deposited tungsten as a mark, it becomes possible for other analyzer to pinpoint the defect position.

In this way, by introducing deposition gas from the gas introduction means 9 while irradiating the electron beam on the specimen, a component of the deposition gas can be deposited in the electron beam irradiation area on the specimen surface and the mark can be formed. Note that it is preferable that the electron beam spot size on the specimen surface at the time of introducing the deposition gas is a spot size of the electron beam that is made narrowest by a capability of the focusing lens 4.

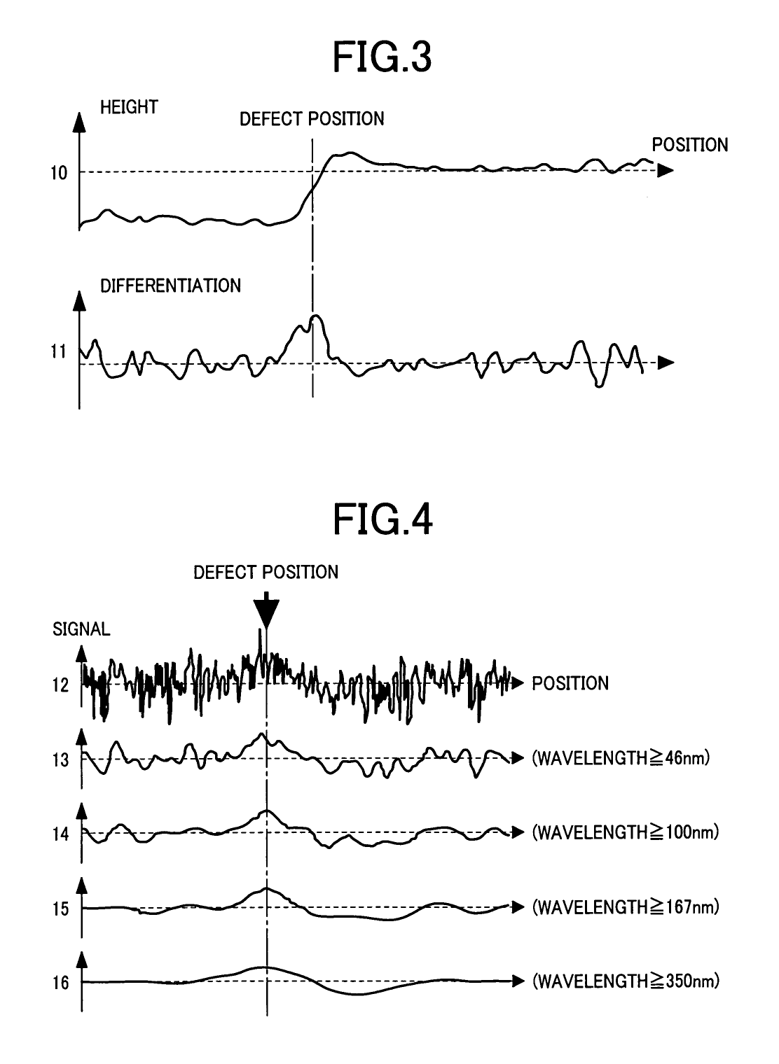

Hereafter, a defect detection method by this invention will be explained. A graph (10) in FIG. 3 corresponds to a sectional view of a dummy defect used this time. In this example, a level difference of about 5 nm was prepared on the magnetic recording media to make the dummy defect. In the figure, a horizontal axis represents a position on the recording media surface and a vertical axis represents a height.

Since a detection signal obtained by irradiating the electron beam on the magnetic recording media surface having this dummy defect is a difference between the two detectors described above, the detection signal becomes as shown in the graph (11) by calculating differentiation from a graph (10).

First, profile information of an area including the defect position is acquired. A manufactured dummy defect recording media is set on the spindle motor 6 of the system shown in FIG. 1, and the media is rotated. Next, a primary electron beam is irradiated onto a track containing the dummy defect, and produced secondary electrons are detected. A graph (12) in FIG. 4 is a signal profile obtained by actually irradiating the electron beam onto the dummy defect shown in the graph (10). Note that the graph (11) and the graph (12) do not show signals in the exactly same location. Since the graph (12) is a graph including electric noise resulting from the detectors and minute unevenness due to the grain size of the media, and the graph includes high frequency noise. Therefore, it is difficult to detect a peak directly by a level difference from the graph (12). Then, the graph (12) is Fourier transformed, the wavelength components less than a certain wavelength are removed from the Fourier transform, and the remaining Fourier transform is inverse Fourier transformed, whereby high frequency components can be removed. This technique functions as the so-called low-pass filter.

Graphs (13), (14), (15), and (16) are graphs that are reconstructed only with frequency components corresponding to wavelengths equal to or more than 46 nm, 100 nm, 167 nm, 350 nm, respectively. In the case of the graphs (13), (14), (15), and (16) from which noise is removed by Fourier transform, when any signal above a certain threshold is detected as a defect candidate, it is understood that a defect being intended to be detected (a portion indicated by an arrow in the figure) is surely included in defect candidates that were narrowed to a certain small number.

Here, signal processing, such as the low-pass filtering and the inverse Fourier transform processing described above, is conducted by the image processing operation control 20. Designating the magnetic grain size of the magnetic recording media by r and a defect size being intended to be detected by d, it is recommendable that the filter based on Fourier transform sets a cut-off frequency by which wavelength components corresponding to features of smaller sizes than a desired value x that satisfies r<x<dare removed. Such a cut-off frequency is set by the system user through information input means. Alternatively, the cut-off frequency may be set as follows: Set-up values of cut-off frequency associated with information of the defect size d and the magnetic grain size r are stored in the image processing operation control 20. An appropriate value is called therefrom using information of the defect size and the crystal grain size entered by the system user as inspection keys.

Although this embodiment has shown the example where one-dimensional data is Fourier transformed and noise is removed, the same processing is also applicable to a two-dimensional image. Moreover, although the example shown in this embodiment is the processing on information corresponding to unevenness differentiation values of the specimen surface, the similar processing is also effective on the unevenness information of the specimen surface.

For noise generated at random, such as noise by vibration of the specimen, it is possible to make such noise relatively small by scanning the same location twice or more and adding signals. Moreover, several locations that give detection of signals that are considered to originate from defects are picked up, and later only these candidate locations are examined again. In that case, it is also possible to identify whether it is a real defect or noise by changing a magnification or scanning speed.

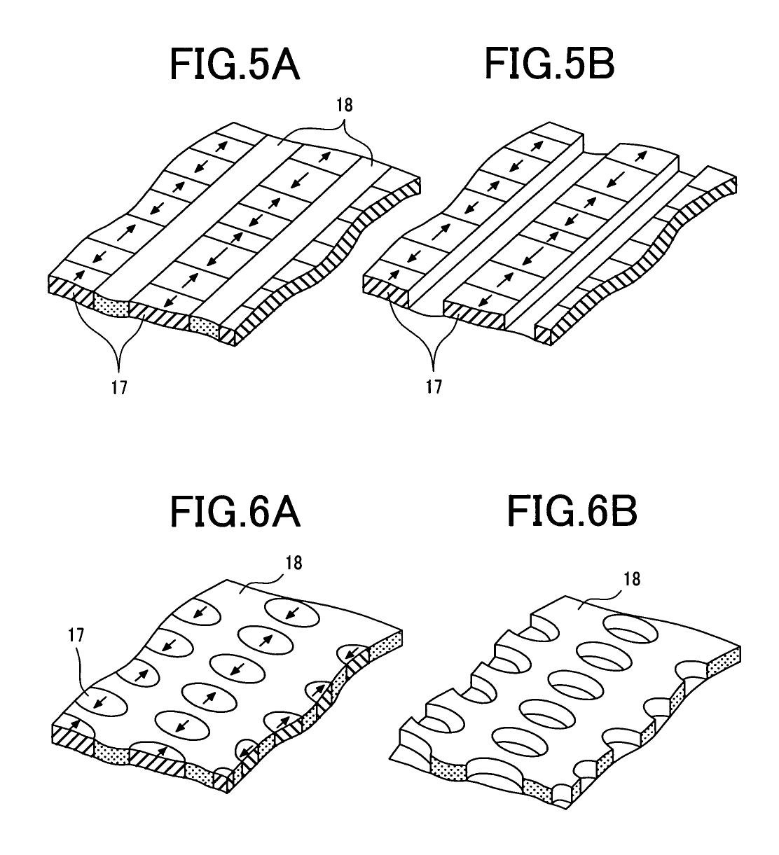

In the case where the specimen 5 is a magnetic recording media composed of a magnetic material part and a non-magnetic material part and is either a discrete track media as shown by FIG. 5A or a patterned media shown by FIG. 6A, although materials are different between a magnetic material 17 and a non-magnetic material 18, it causes no problem because this system is a system for detecting unevenness.

FIG. 5B and FIG. 6B show states before trenches or holes formed on the media are buried with the non-magnetic material 18 or the magnetic material 17, respectively. When performing defect inspection in such a state, trenches and holes hinder defect detection. In that case, what is necessary is just to determine not only the lower limit of the Fourier transform filter but also it supper limit. Designating the magnetic grain size by r, a defect size being intended to be detected by d, and a wavelength of the trench or hole by h, it is recommendable that a filter based on Fourier transform is such that removes wavelength components corresponding to features smaller than a desired value x where x satisfies r<x<d and wavelength components corresponding to features having a size equal to or more than h.

For example, in the case of a trench having an interval of 200 nm, defect detection is performed after removing a wavelength component corresponding to not more than a desired value and a wavelength component of 200 nm or more. Here, the desired value is between the grain size of the specimen 5 and a defect size being intended to be detected, both inclusive. Since a defect is detected from data from which unevenness resulting from the trench is removed, defect detection becomes easy. It is also effective to remove only a wavelength equivalent to the trench rather than removing all the wavelengths equal to or more than the upper limit.

Note that, the above-mentioned technique by this invention is applicable to not only magnetic recording media but also optical recording media, magneto-optical recording media, and semiconductor wafers.

As explained in detail in the foregoing, according to this invention, defect detection of a recording media can be attained at high speed and with high resolution by the defect inspection system and the defect inspection method using an electron beam. In addition, information of the existence or absence of defects of inspected parts inspected by the defect inspection system can be used for works of causative analysis of defects etc. that will be conducted after that by accumulating and managing the defect information.

What is claimed is:

1. A defect inspection system for a recording media, comprising:
an electron optics system for irradiating and scanning a recording media surface with an electron beam emitted from an electron source through a deflection electrode and a focusing lens;
position control means for rotating and translating the recording media;
detection means for detecting electrons produced secondarily from the recording media surface;
means for calculating unevenness information of the recording media surface or unevenness differentiation values from a signal of the detection means;
means for detecting a defect on the recording media surface by Fourier transforming the unevenness information or unevenness differentiation values; and
gas introduction means for introducing deposition gas onto the recording media surface.

2. The defect inspection system for a recording media according to claim 1, wherein the focusing lens can alter a spot size of the electron beam being irradiated on the recording media.

3. The defect inspection system for a recording media according to claim 2, wherein, in the case where the recording media is a magnetic recording media, the spot size of the electron beam in an initial inspection stage is not less than a grain size and not more than a defect size.

4. The defect inspection system for a recording media according to claim 1, wherein the position control means has a spindle motor for rotating the recording media and a feed stage for translating it in X-Y directions in the recording media plane, and the defect inspection system is configured to detect electrons produced secondarily from the recording media surface by rotating the recording media while irradiating the electron beam on the recording media.

5. The defect inspection system for a recording media according to claim 1, wherein the detection means equipped with two or more secondary electron detectors for calculating unevenness information of the recording media surface or unevenness differentiation values from differences between signal quantities of the opposing secondary electron detectors.

6. The defect inspection system for a recording media according to claim 1, wherein the gas introduction means deposits a component of the deposition gas in the electron beam irradiation area on the recording media surface to form a mark by introducing the deposition gas while irradiating the electron beam on the recording media.

7. The defect inspection system for a recording media according to claim 6, wherein the spot size of the electron beam on the recording media surface at the time of introducing the deposition gas is a spot size of the electron beam that is made narrowest by a capability of the focusing lens.

8. A defect inspection method for a recording media, comprising the steps of:
detecting electrons produced secondarily from a recording media by rotating the recording media while irradiating an electron beam on a surface of the recording media;
calculating unevenness information of the recording media surface or unevenness differentiation values from a detection signal;
detecting a defect on the recording media surface by Fourier transforming the unevenness information or unevenness differentiation values; and
depositing a component of deposition gas in a detected defect position on the recording media surface by introducing the deposition gas onto the recording media surface while irradiating the electron beam on the recording media.

9. The defect inspection method for a recording media according to claim 8, wherein the unevenness of the recording media surface or a group of its differentiation values is one- or two-dimensional information.

10. The defect inspection method for a recording media according to claim 8, wherein, in the case where the recording media is a magnetic recording media, wavelength components corresponding to not more than a desired value existing between the grain size of the magnetic recording media and a defect size being intended to be detected, both inclusive, are removed.

11. The defect inspection method for a recording media according to claim 10, wherein a wavelength component of a continuous structure artificially made on the recording media surface is further removed from the Fourier transformed information from which wavelength components corresponding to not more than the desired value have been removed.

12. The defect inspection method for a recording media according to claim 10, wherein the Fourier transformed information is inverse Fourier transformed and a defect on the recording media surface is detected from the obtained information.

13. A defect inspection system, comprising:
an electron optics system for irradiating and scanning a magnetic recording media with an electron beam emitted from an electron source through a deflection electrode and a focusing lens;
position control means for rotating and translating the magnetic recording media;
detection means equipped with two or more detectors for detecting secondary electrons from the surface of the magnetic recording media;
means for calculating unevenness information of the magnetic recording media surface or unevenness differentiation values from differences between signal quantities of the opposing detectors;
means for detecting a defect on the magnetic recording media surface by Fourier transforming the unevenness information or unevenness differentiation values;
gas introduction means for introducing deposition gas onto the magnetic recording media surface; and
means for depositing a component of the disposition gas in the electron beam irradiation area on the magnetic recording media surface to form a mark by introducing the deposition gas while irradiating the electron beam on the magnetic recording media.
